(19) United States
(12) Patent Application Publication
(10) Pub. No.: US 2026/0107648 A1
(43) Pub. Date: Apr. 16, 2026

(54) DISPLAY DEVICE AND ELECTRONIC DEVICE

(71) Applicant: Samsung Display Co., Ltd., Yongin-si (KR)

(72) Inventor: Chun Gi YOU, Yongin-si (KR)

(21) Appl. No.: 19/275,273

(22) Filed: Jul. 21, 2025

(30) Foreign Application Priority Data
Oct. 14, 2024 (KR) 10-2024-0139704

(51) Int. Cl. H10K 59/131; H10K 59/121; H10K 59/35

(52) U.S. Cl. CPC H10K 59/131; H10K 59/1213; H10K 59/1216; H10K 59/35

(57) ABSTRACT

A display device includes: a substrate having transistors of sub-pixels thereon; and a first electrode layer on the substrate, and including first conductive patterns connected to a first electrode, a second electrode, and a gate electrode of the transistors. The first conductive patterns include first conductive lines extending in a first direction to be shared with a plurality of the sub-pixels, and each of the first conductive lines repeatedly includes a protrusion portion and a concave portion along the first direction. The protrusion portion and the concave portion of one first conductive line face the concave portion and the protrusion portion, respectively, of another first conductive line adjacent to the one first conductive line in a second direction crossing the first direction from among the first conductive lines.

### CROSS-REFERENCE TO RELATED APPLICATION

The present application claims priority to and the benefit of Korean Patent Application No. 10-2024-0139704, filed on Oct. 14, 2024, in the Korean Intellectual Property Office, the entire disclosure of which is incorporated by reference herein.

### BACKGROUND

### 1. Field Aspects of embodiments of the present disclosure relate to a display device and an electronic device.

### 2. Description of the Related Art

As information technology develops, the importance of a display device, which is a connection medium between a user and information, is emerging. In response, uses of a display device, such as a liquid crystal display device and an organic light emitting display device, are increasing.

As the display device becomes higher in resolution, a gap between a line and another line is narrowing. In this case, a short may occur between adjacent lines.

The above information disclosed in this Background section is for enhancement of understanding of the background of the present disclosure, and therefore, it may contain information that does not constitute prior art.

### SUMMARY

Embodiments of the present disclosure may be directed to a display device and an electronic device including a layout capable of securing a gap between adjacent lines.

According to one or more embodiments of the present disclosure, a display device includes: a substrate having transistors of sub-pixels thereon; and a first electrode layer on the substrate, and including first conductive patterns connected to a first electrode, a second electrode, and a gate electrode of the transistors. The first conductive patterns include first conductive lines extending in a first direction to be shared with a plurality of the sub-pixels, and each of the first conductive lines repeatedly includes a protrusion portion and a concave portion along the first direction. The protrusion portion and the concave portion of one first conductive line face the concave portion and the protrusion portion, respectively, of another first conductive line adjacent to the one first conductive line in a second direction crossing the first direction from among the first conductive lines.

In an embodiment, each of the sub-pixels may include: a first transistor including a gate electrode connected to a first node, a first electrode connected to a first power line, and a second electrode connected to a third node; a second transistor including a gate electrode connected to a first gate line, a first electrode connected to a data line, and a second electrode connected to a second node; a third transistor including a gate electrode connected to a second gate line, a first electrode connected to the first node, and a second electrode connected to the third node; a fourth transistor including a gate electrode connected to a first emission control line, a first electrode connected to the third node, and a second electrode connected to a fourth node; a fifth transistor including a gate electrode connected to a second emission control line, a first electrode connected to the fourth node, and a second electrode connected to a first initialization line; a sixth transistor including a gate electrode connected to a third gate line, a first electrode connected to a second initialization line, and a second electrode connected to the second node; and a seventh transistor including a gate electrode connected to a fourth gate line, a first electrode connected to the second initialization line, and a second electrode connected to the first node.

In an embodiment, the one first conductive line and the other first conductive line may include the first gate line and the first initialization line that may be adjacent to each other in the second direction, the protrusion portion of the first gate line and the concave portion of the first initialization line may face each other, and the concave portion of the first gate line and the protrusion portion of the first initialization line may face each other.

In an embodiment, a distance in the second direction between the protrusion portion of the first gate line and the concave portion of the first initialization line may be equal to a distance in the second direction between the concave portion of the first gate line and the protrusion portion of the first initialization line.

In an embodiment, the protrusion portion of the first gate line may be located on a first sub-pixel and a third sub-pixel from among the sub-pixels, and the concave portion of the first gate line may be located on a second sub-pixel between the first sub-pixel and the third sub-pixel from among the sub-pixels. The concave portion of the first initialization line may be located on the first sub-pixel and the third sub-pixel, and the protrusion portion of the first initialization line may be located on the second sub-pixel.

In an embodiment, the one first conductive line and the other first conductive line may include the second gate line and the first emission control line that may be adjacent to each other in the second direction, the protrusion portion of the second gate line and the concave portion of the first emission control line may face each other, and the concave portion of the second gate line and the protrusion portion of the first emission control line may face each other.

In an embodiment, a distance in the second direction between the protrusion portion of the second gate line and the concave portion of the first emission control line may be equal to a distance in the second direction between the concave portion of the second gate line and the protrusion portion of the first emission control line.

In an embodiment, the protrusion portion of the first emission control line may be located on a first sub-pixel and a third sub-pixel from among the sub-pixels, and the concave portion of the first emission control line may be located on a second sub-pixel between the first sub-pixel and the third sub-pixel from among the sub-pixels. The concave portion of the second gate line may be located on the first sub-pixel and the third sub-pixel, and the protrusion portion of the second gate line may be located on the second sub-pixel.

In an embodiment, the one first conductive line and the other first conductive line may include the fourth gate line and the second emission control line that may be adjacent to each other in the second direction, the protrusion portion of the fourth gate line and the concave portion of the second emission control line may face each other, and the concave portion of the fourth gate line and the protrusion portion of the second emission control line may face each other.

In an embodiment, a distance in the second direction between the protrusion portion of the fourth gate line and the concave portion of the second emission control line may be equal to a distance in the second direction between the concave portion of the fourth gate line and the protrusion portion of the second emission control line.

In an embodiment, the protrusion portion of the fourth gate line may be located on a first sub-pixel and a third sub-pixel from among the sub-pixels, and the concave portion of the fourth gate line may be located on a second sub-pixel between the first sub-pixel and the third sub-pixel from among the sub-pixels. The concave portion of the second emission control line may be located on the first sub-pixel and the third sub-pixel, and the protrusion portion of the second emission control line may be located on the second sub-pixel.

In an embodiment, each of the second initialization line, the first power line, and the third gate line may extend in a zigzag form along the first direction.

In an embodiment, coordinates in the second direction of the second initialization line, the first power line, and the third gate line may vary in a unit of a sub-pixel.

In an embodiment, the display device may further include a second electrode layer on the first electrode layer, and including second conductive patterns connected to the first conductive patterns. The second conductive patterns may include island patterns and second conductive lines extending in the second direction, and each of the second conductive lines may include a concave portion corresponding to an adjacent island pattern from among the island patterns.

In an embodiment, the second conductive lines may include dedicated lines of respective sub-pixels from among the sub-pixels.

In an embodiment, the second conductive lines may include the first initialization line, the second initialization line, and the first power line.

In an embodiment, the island patterns may include the first node, the second node, the fourth node, the data line, and the first power line.

In an embodiment, island patterns corresponding to the second node, the fourth node, and the first power line from among the island patterns may be located between concave portions of the first initialization line and concave portions of the second initialization line, and an island pattern corresponding to the first node from among the island patterns may be located between a concave portion of the second initialization line and a concave portion of the first power line.

In an embodiment, each of the sub-pixels may further include: a capacitor between the first node and the second node; and a light emitting element including an anode electrode connected to the fourth node, and a cathode electrode connected to a second power line.

According to one or more embodiments of the present disclosure, an electronic device includes: a processor configured to provide image data; and a display device configured to display an image based on the image data, the display device including: a substrate having transistors of sub-pixels thereon; and a first electrode layer on the substrate, and including first conductive patterns connected to a first electrode, a second electrode, and a gate electrode of the transistors. The first conductive patterns includes first conductive lines extending in a first direction to be shared with a plurality of the sub-pixels, and each of the first conductive lines repeatedly includes a protrusion portion and a concave portion along the first direction. The first conductive lines adjacent to each other in a second direction crossing the first direction from among the first conductive lines include the protrusion portion and the concave portion that face each other.

A display device and an electronic device according to some embodiments of the present disclosure may include a layout capable of securing a gap between adjacent lines.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative embodiments with reference to the accompanying drawings, in which:

FIG. 1 is a block diagram illustrating a display device according to an embodiment;

FIG. 2 is a diagram illustrating a sub-pixel according to an embodiment;

FIG. 3 is a plan view illustrating a display panel of FIG. 1 according to an embodiment;

FIG. 4 is an exploded perspective view illustrating a portion of the display panel of FIG. 3;

FIG. 5 is a plan view illustrating one of the pixels of FIG. 4 according to an embodiment;

FIG. 6 is a cross-sectional view taken along the line I-I′ of FIG. 5 according to an embodiment;

FIG. 7 is a cross-sectional view illustrating a portion of a light emitting structure included in one of the first to third light emitting elements of FIG. 6 according to an embodiment;

FIG. 8 is a cross-sectional view illustrating a portion of a light emitting structure included in one of the first to third light emitting elements of FIG. 6 according to an embodiment;

FIG. 9 is a drawing illustrating a pixel circuit layer of FIG. 6;

FIGS. 10-17 are drawings illustrating electrode layers of FIG. 9;

FIG. 18 is a block diagram illustrating a display system according to an embodiment;

FIG. 19 is a perspective view illustrating an application example of the display system of FIG. 18; and

FIG. 20 is a drawing illustrating a head mounted display device of FIG. 19 worn by a user.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques.

Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,”“utilizing,”and “utilized,”respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

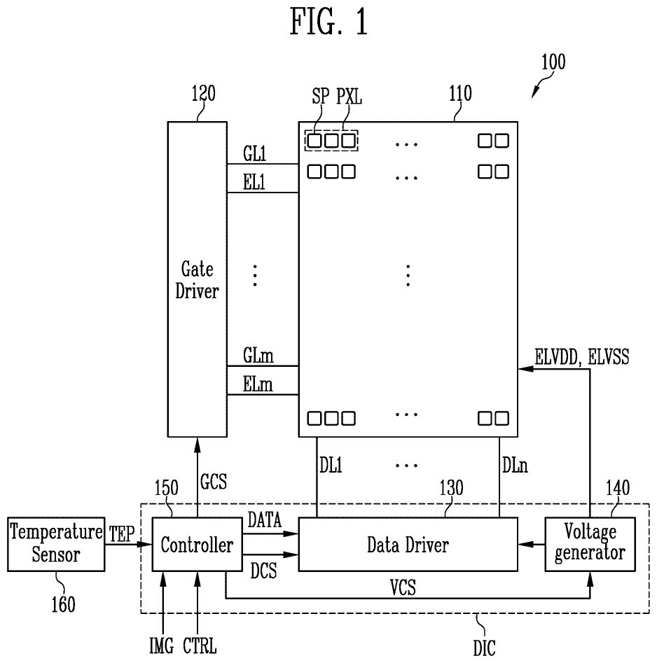

FIG. 1 is a block diagram illustrating a display device according to an embodiment.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through gate lines GL1 to GLm, where m is an integer greater than 1. The sub-pixels SP may be connected to the data driver 130 through data lines DL1 to DLn, where n is an integer greater than 1.

Each of the sub-pixels SP may include at least one light emitting element to generate light. Accordingly, each of the sub-pixels SP may generate light of a desired color (e.g., a specific or predetermined color), such as red, green, blue, cyan, magenta, or yellow. Two or more sub-pixels among the sub-pixels SP may configure (e.g., may be included in) one pixel PXL. For example, as shown in FIG. 1, three sub-pixels may configure one pixel PXL.

The gate driver 120 is connected to the sub-pixels SP arranged in a row direction through the gate lines GL1 to GLm. The gate driver 120 may output gate signals to the gate lines GL1 to GLm in response to a gate control signal GCS. In some embodiments, the gate control signal GCS may include a start signal indicating a start of each frame, a horizontal synchronization signal for outputting the gate signals in synchronization with a timing at which data signals are applied, and the like.

In some embodiments, emission control lines EL1 to ELm connected to the sub-pixels SP of the row direction may be further provided. In this case, the gate driver 120 may include an emission control driver to control the emission control lines EL1 to ELm, and the emission control driver may operate under a control of the controller 150.

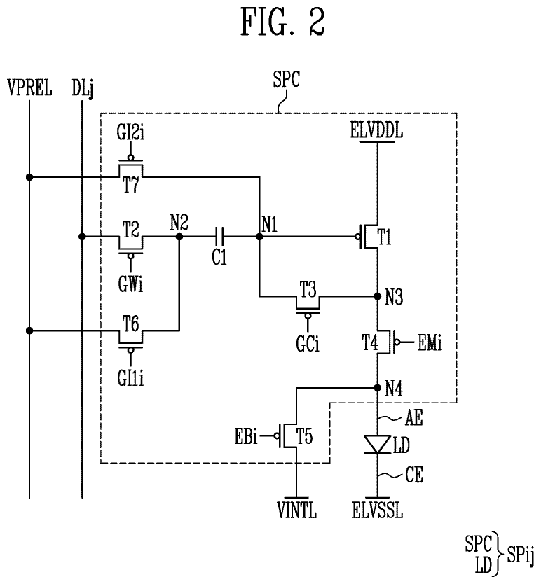

Each of the gate lines GL1 to GLm may include a plurality of sub-gate lines (e.g., refer to FIG. 2). In addition, each of the emission control lines EL1 to ELm may include a plurality of sub-emission control lines (e.g., refer to FIG. 2).

The gate driver 120 may be located on one side of the display panel 110. However, the present disclosure is not limited thereto. For example, the gate driver 120 may be divided into two or more physically and/or logically divided drivers, and such drivers may be located on one side of the display panel 110 and another side of the display panel 110 opposite to the one side. As described above, the gate driver 120 may be located around the display panel 110 in various suitable shapes according to various embodiments as needed or desired.

The data driver 130 is connected to the sub-pixels SP arranged in a column direction through the data lines DL1 to DLn. The data driver 130 receives image data DATA and a data control signal DCS from the controller 150. The data driver 130 operates in response to the data control signal DCS. In some embodiments, the data control signal DCS may include a source start pulse, a source shift clock, a source output enable signal, and the like.

The data driver 130 may apply data signals having grayscale voltages (e.g., gamma voltages) corresponding to the image data DATA to the data lines DL1 to DLn using voltages from the voltage generator 140. The data signals corresponding to the image data DATA may be applied to the data lines DL1 to DLm in a case where the gate signal is applied to each of the gate lines GL1 to GLm. Accordingly, the corresponding (e.g., selected) sub-pixels SP may generate light corresponding to the data signals. Accordingly, an image is displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages, and may provide the generated voltages to the components of the display device 100. For example, the voltage generator 140 may generate the plurality of voltages by receiving an input voltage from the outside of the display device 100, adjusting the received voltage, and regulating the adjusted voltage.

The voltage generator 140 may generate a first power voltage ELVDD and a second power voltage ELVSS. The generated first and second power voltages ELVDD and ELVSS may be provided to the sub-pixels SP. The first power voltage ELVDD may have a relatively high voltage level, and the second power voltage ELVSS may have a voltage level lower than the voltage level of the first power voltage ELVDD. In other embodiments, the first power voltage ELVDD or the second power voltage ELVSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a reference voltage (e.g., a predetermined reference voltage) may be applied to the data lines DL1 to DLn, and the voltage generator 140 may generate the reference voltage.

The controller 150 controls the overall operations of the display device 100. The controller 150 receives input image data IMG and a control signal CTRL from the outside for controlling a display of the input image data IMG. The controller 150 may provide the gate control signal GCS, the data control signal DCS, and the voltage control signal VCS in response to the control signal CTRL.

The controller 150 may convert the input image data IMG to be suitable for the display device 100 or the display panel 110, and may output the image data DATA. In some embodiments, the controller 150 may output the image data DATA by aligning the input image data IMG to be suitable for the sub-pixels SP in a unit of a row (e.g., of a row unit).

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, or the controller 150 may be provided as a component distinguished from the driver integrated circuit DIC.

The display device 100 may include at least one temperature sensor 160. The temperature sensor 160 may sense a temperature around the temperature sensor 160, and may generate temperature data TEP indicating the sensed temperature. In some embodiments, the temperature sensor 160 may be located adjacent to the display panel 110 and/or the driver integrated circuit DIC.

The controller 150 may control various operations of the display device 100 in response to the temperature data TEP. In some embodiments, the controller 150 may adjust a luminance of the image output from the display panel 110 in response to the temperature data TEP. For example, the controller 150 may control the data signals and the first and second power voltages ELVDD and ELVSS by controlling the components such as the data driver 130 and/or the voltage generator 140.

FIG. 2 is a drawing illustrating a sub-pixel according to an embodiment.

In FIG. 2, among the sub-pixels SP of FIG. 1, a sub-pixel SPij arranged in an i-th row (where i is an integer greater than or equal to 1 and less than or equal to m) and a j-th column (where j is an integer greater than or equal to 1 and less than or equal to n) is illustrated as a representative example. First to fourth gate lines GWi, GCi, GI1i, and GI2i may correspond to the sub-gate lines of an i-th gate line in FIG. 1. In addition, first and second emission control lines EMi and EBi may correspond to the sub-emission control lines of an i-th emission control line in FIG. 1.

Referring to FIG. 2, the sub-pixel SPij may include a sub-pixel circuit SPC and a light emitting element LD. The sub-pixel circuit SPC may include first to seventh transistors T1 to T7 and a capacitor C1, which are connected to the light emitting element LD.

The first to seventh transistors T1 to T7 may be P-type transistors. Each of the transistors T1 to T7 may be a metal oxide silicon field effect transistor (MOSFET). However, the present disclosure is not limited thereto. For example, at least one of the transistors T1 to T7 may be replaced with an N-type transistor.

In some embodiments, the transistors T1 to T7 may include an amorphous silicon semiconductor, a monocrystalline silicon, a polycrystalline silicon semiconductor, an oxide semiconductor, or the like.

The first transistor T1 may have a gate electrode connected to a first node N1, a first electrode connected to a first power line ELVDDL, and a second electrode connected to a third node N3. The first transistor T1 may control an amount of a driving current based on a voltage difference between the first node N1 and the third node N3. A driving current path refers to a path connecting the first power line ELVDDL, the first transistor T1, the fourth transistor T4, the light emitting element LD, and a second power line ELVSSL. The first power voltage ELVDD may be applied to the first power line ELVDDL, and the second power voltage ELVSS may be applied to the second power line ELVSSL (e.g., refer to FIG. 1). The driving current refers to a current flowing through the driving current path. The first transistor T1 may be referred to as a driving transistor.

The second transistor T2 may have a gate electrode connected to the first gate line GWi, a first electrode connected to the data line DLj, and a second electrode connected to the second node N2. The second transistor T2 may be turned on in case that a first gate signal of a turn-on level (e.g., a low level) is applied to the first gate line GWi, and may apply a data signal (e.g., a data voltage) of the data line DLj to the second node N2.

The third transistor T3 may have a gate electrode connected to the second gate line GCi, a first electrode connected to the first node N1, and a second electrode connected to the third node N3. The third transistor T3 may be turned on in case that a second gate signal of a turn-on level (e.g., a low level) is applied to the second gate line GCi, and may diode-connect the first transistor T1. The third transistor T3 may be used to reflect a threshold voltage of the first transistor T1 to the first node N1. For example, a voltage of the first node N1 may increase through the third transistor T3 in case that a current flows from the first power line ELVDDL to the third node N3 through the first transistor T1. In this case, the first transistor T1 may be turned off when a voltage difference between the first electrode (e.g., a source electrode) and the gate electrode of the first transistor T1 corresponds to the threshold voltage, and a voltage corresponding to the threshold voltage of the first transistor T1 may be stored in the first node N1.

The fourth transistor T4 may have a gate electrode connected to the first emission control line EMi, a first electrode connected to the third node N3, and a second electrode connected to a fourth node N4. The fourth transistor T4 may be turned on when a first emission control signal of a turn-on level (e.g., a low level) is applied to the first emission control line EMi, to supply the driving current to the light emitting element LD.

The fifth transistor T5 may have a gate electrode connected to a second emission control line EBi, a first electrode connected to the fourth node N4, and a second electrode connected to a first initialization line VINTL. The fifth transistor T5 may be turned on when a second emission control signal of a turn-on level (e.g., a low level) is applied to the second emission control line EBi, to apply a first initialization voltage of the first initialization line VINTL to the fourth node N4. As the first initialization voltage is decreased, low-grayscale expression may be improved, and as the first initialization voltage is increased, a light emission delay may be prevented or reduced. A size of the first initialization voltage may also be determined according to a characteristic of the light emitting element LD for each color.

The sixth transistor T6 may have a gate electrode connected to the third gate line GI1i, a first electrode connected to a second initialization line VPREL, and a second electrode connected to the second node N2. The sixth transistor T6 may be turned on when a third gate signal of a turn-on level (e.g., a low level) is applied to the third gate line GI1i, to supply a second initialization voltage of the second initialization line VPREL to the second node N2. In this case, a voltage of a first electrode of the capacitor C1 may be initialized.

The seventh transistor T7 may have a gate electrode connected to the fourth gate line GI2i, a first electrode connected to the second initialization line VPREL, and a second electrode connected to the first node N1. The seventh transistor T7 may be turned on when a fourth gate signal of a turn-on level (e.g., a low level) is applied to the fourth gate line GI2i, to supply a second initialization voltage of the second initialization line VPREL to the first node N1. In this case, a voltage of a second electrode of the capacitor C1 may be initialized.

The capacitor C1 may be connected between the first node N1 and the second node N2. For example, the first electrode of the capacitor C1 may be connected to the second node N2, and the second electrode thereof may be connected to the first node N1.

The light emitting element LD may have an anode electrode AE connected to the fourth node N4, and a cathode electrode CE connected to the second power line ELVSSL. The light emitting element LD may further include a light emitting layer between the anode electrode AE and the cathode electrode CE. The light emitting element LD may emit light having a luminance corresponding to the amount of the driving current when the driving current is supplied.

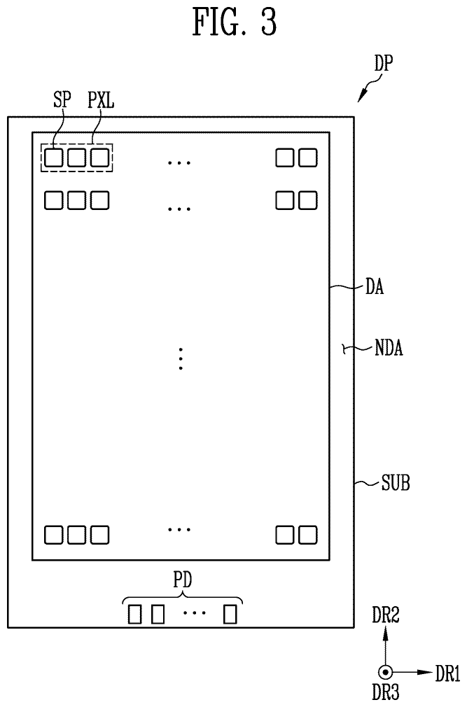

FIG. 3 is a plan view illustrating the display panel of FIG. 1 according to an embodiment.

Referring to FIG. 3, a display panel DP may correspond to the display panel 110 of FIG. 1, and may include a display area DA and a non-display area NDA. The display panel DP displays an image through the display area DA. The non-display area NDA is located around the display area DA.

The display panel DP may include a substrate SUB, the sub-pixels SP, and pads PD.

the display panel DP may be located very close to user's eyes when the display panel DP is used as a display screen of a head mounted display (HMD), a virtual reality (VR) device, a mixed reality (MR) device, an augmented reality (AR) device, or the like. In this case, the sub-pixels SP having a relatively high integration degree may be desired. The substrate SUB may be provided as a silicon substrate to increase the integration degree of the sub-pixels SP. The sub-pixels SP and/or the display panel DP may be formed on the substrate SUB, which may be the silicon substrate. The display device 100 (e.g., refer to FIG. 1) including the display panel DP formed on the substrate SUB, which is the silicon substrate, may be referred to as an OLED on silicon (OLEDoS) display device.

The sub-pixels SP are located in the display area DA on the substrate SUB. The sub-pixels SP may be arranged in a matrix shape along a first direction DR1, and a second direction DR2 crossing the first direction DR1. However, the present disclosure is not limited thereto. For example, the sub-pixels SP may be arranged in a zigzag shape along the first direction DR1 and the second direction DR2. For example, the sub-pixels SP may be arranged in a diamond shape (e.g., a PENTILE® shape, PENTILE® being a duly registered trademark of Samsung Display Co., Ltd.). The first direction DR1 may be a row direction, and the second direction DR2 may be a column direction.

Two or more sub-pixels among the plurality of sub-pixels SP may configure one pixel PXL.

A component for controlling the sub-pixels SP may be located in the non-display area NDA on the substrate SUB. For example, lines connected to the sub-pixels SP, such as the gate lines GL1 to GLm and the data lines DL1 to DLn of FIG. 1, may be located in the non-display area NDA.

At least one of the gate driver 120, the data driver 130, the voltage generator 140, the controller 150, or the temperature sensor 160 of FIG. 1 may be integrated in the non-display area NDA of the display panel DP. In some embodiments, the gate driver 120 of FIG. 1 may be mounted on the display panel DP, and may be located in the non-display area NDA. In other embodiments, the gate driver 120 may be implemented as an integrated circuit separated from the display panel DP. In some embodiments, the temperature sensor 160 may be located in the non-display area NDA to sense a temperature of the display panel DP.

The pads PD are located in the non-display area NDA on the substrate SUB. The pads PD may be electrically connected to the sub-pixels SP through lines. For example, the pads PD may be connected to the sub-pixels SP through the data lines DL1 to DLn.

The pads PD may interface the display panel DP to other components of the display device 100 (e.g., refer to FIG. 1). In some embodiments, voltages and signals used for an operation of the components included in the display panel DP may be provided from the driver integrated circuit DIC of FIG. 1 through the pads PD. For example, the data lines DL1 to DLn may be connected to the driver integrated circuit DIC through the pads PD. For example, the first and second power voltages ELVDD and ELVSS may be received from the driver integrated circuit DIC through the pads PD. For example, the gate control signal GCS may be transmitted from the driver integrated circuit DIC to the gate driver 120 through the pads PD when the gate driver 120 is mounted on the display panel DP.

In some embodiments, a circuit board may be electrically connected to the pads PD using a conductive adhesive member, such as an anisotropic conductive film. In this case, the circuit board may be a flexible circuit board (FPCB) or a flexible film having a flexible material. The driver integrated circuit DIC may be mounted on the circuit board to be electrically connected to the pads PD.

In some embodiments, the display area DA may have various suitable shapes. The display area DA may have a closed loop shape including straight and/or curved sides. For example, the display area DA may have various suitable shapes, such as a polygon, a circle, a semicircle, and an ellipse.

In some embodiments, the display panel DP may have a flat or substantially flat display surface. In other embodiments, the display panel DP may have a display surface that is at least partially round. In some embodiments, the display panel DP may be bendable, foldable, or rollable. In these cases, the display panel DP and/or the substrate SUB may include various suitable materials having a flexible property.

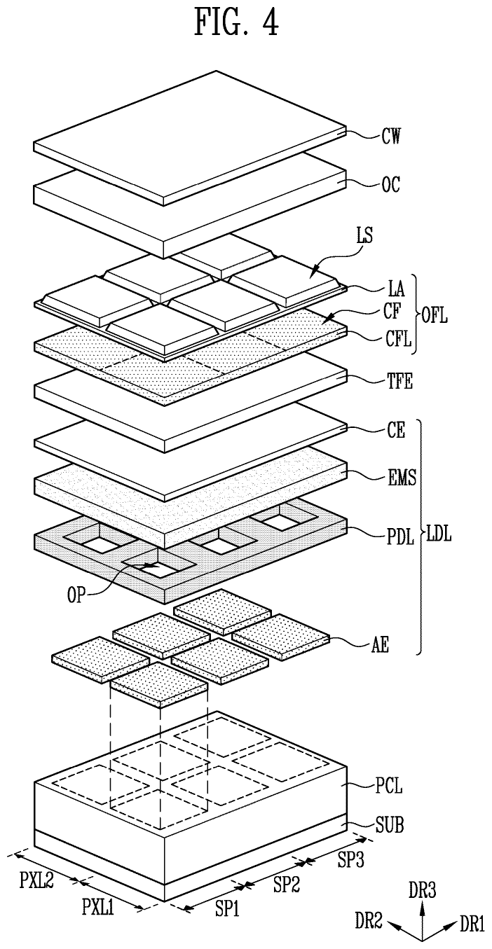

FIG. 4 is an exploded perspective view illustrating a portion of the display panel of FIG. 3. In FIG. 4, for convenience of illustration, a portion of the display panel DP corresponding to two pixels PXL1 and PXL2 among the pixels PXL of FIG. 3 is schematically shown. A portion of the display panel DP corresponding to the other remaining pixels PXL may be configured in the same or substantially the same (or similar) manner.

Referring to FIGS. 3 and 4, each of the first and second pixels PXL1 and PXL2 may include first to third sub-pixels SP1, SP2, and SP3. However, the present disclosure is not limited thereto. For example, each of the first and second pixels PXL1 and PXL2 may include four sub-pixels or two sub-pixels.

In FIG. 4, the first to third sub-pixels SP1, SP2, and SP3 have quadrangle shapes when viewed in a third direction DR3 (e.g., in a plan view) crossing the first and second directions DR1 and DR2, and may have sizes that are equal or substantially equal to each other. However, the present disclosure is not limited thereto. The first to third sub-pixels SP1, SP2, and SP3 may be variously modified to have various suitable shapes as needed or desired.

The display panel DP may include the substrate SUB, a pixel circuit layer PCL, a light emitting element layer LDL, an encapsulation layer TFE, an optical function layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium.

The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In other embodiments, the substrate SUB may include a polyimide (PI) substrate.

The pixel circuit layer PCL is located on the substrate SUB. The substrate SUB and/or the pixel circuit layer PCL may include insulating layers, and conductive patterns located between the insulating layers. The conductive patterns of the pixel circuit layer PCL may function as at least a portion of circuit elements, lines, and the like. The conductive patterns may include copper, but the present disclosure is not limited thereto.

The circuit elements may include the sub-pixel circuit SPC (e.g., refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping with the semiconductor portion. In some embodiments, the semiconductor portion may be included in the substrate SUB, and the gate electrode may be included in the pixel circuit layer PCL as a conductive pattern of the pixel circuit layer PCL, when the substrate SUB is provided as a silicon substrate. In some embodiments, the semiconductor portion and the gate electrode may be included in the pixel circuit layer PCL when the substrate SUB is provided as a glass substrate or a PI substrate. Each capacitor may include electrodes that are spaced apart from each other. For example, each capacitor may include electrodes spaced apart from each other on a plane defined by the first and second directions DR1 and DR2. For example, each capacitor may include electrodes spaced apart from each other in the third direction DR3, with an insulating layer interposed between the electrodes.

The lines of the pixel circuit layer PCL may include signal lines connected to each of the first to third sub-pixels SP1, SP2, and SP3, for example, such as a gate line, an emission control line, a data line, and the like. The lines may further include the first power voltage line ELVDDL of FIG. 2. In addition, the lines may further include the second power voltage line ELVSSL of FIG. 2.

The light emitting element layer LDL may include the anode electrodes AE, a pixel defining layer PDL, a light emitting structure EMS, and the cathode electrode CE.

The anode electrodes AE may be located on the pixel circuit layer PCL. The anode electrodes AE may contact the circuit elements of the pixel circuit layer PCL.

The anode electrodes AE may include an opaque conductive material capable of reflecting light, but the present disclosure is not limited thereto.

The pixel defining layer PDL is located on the anode electrodes AE. The pixel defining layer PDL may include an opening OP exposing a portion of each of the anode electrodes AE. According to the opening OP of the pixel defining layer PDL, emission areas respectively corresponding to the first to third sub-pixels SP1 to SP3 may be defined. As another example, the emission areas corresponding to the first to third sub-pixels SP1 to SP3 may be defined according to the anode electrodes AE. In an area adjacent to a boundary between neighboring sub-pixels, the pixel defining layer PDL may include a separator that causes a formation of a discontinuous portion (e.g., a discontinuity) in the light emitting structure EMS. In this case, the emission areas respectively corresponding to the first to third sub-pixels SP1 to SP3 may be defined according to the separators of the pixel defining layer PDL.

In some embodiments, the pixel defining layer PDL may include an inorganic material. In this case, the pixel defining layer PDL may include a plurality of stacked inorganic layers. For example, the pixel defining layer PDL may include silicon oxide (SiOx) and silicon nitride (SiNx). In other embodiments, the pixel defining layer PDL may include an organic material. However, the material of the pixel defining layer PDL is not limited thereto.

The light emitting structure EMS may be located on the anode electrodes AE exposed by the opening OP of the pixel defining layer PDL. The light emitting structure EMS may include a light emitting layer to generate light, an electron transport layer to transport an electron, a hole transport layer to transport a hole, and the like.

In some embodiments, the light emitting structure EMS may fill the opening OP of the pixel defining layer PDL, and may be entirely located on the pixel defining layer PDL. In other words, the light emitting structure EMS may extend across the first to third sub-pixels SP1 to SP3. In this case, at least a portion of the layers in the light emitting structure EMS may be disconnected or bent at boundaries between the first to third sub-pixels SP1 to SP3. However, the present disclosure is not limited thereto. For example, portions of the light emitting structure EMS corresponding to the first to third sub-pixels SP1 to SP3 may be separated from each other, and each of the portions may be located in a corresponding opening OP of the pixel defining layer PDL.

The cathode electrode CE may be located on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may include a metal material or a transparent conductive material to have a relatively thin thickness. In some embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), or a suitable mixture thereof. However, the material of the cathode electrode CE is not limited thereto.

Any of the anode electrodes AE, a portion of the light emitting structure EMS overlapping with it, and a portion of the cathode electrode CE overlapping with it may configure one light emitting element LD (e.g., refer to FIG. 2). In other words, each of the light emitting elements of the first to third sub-pixels SP1 to SP3 may include one anode electrode, a portion of the light emitting structure EMS overlapping with it, and a portion of the cathode electrode CE overlapping with it. In each of the first to third sub-pixels SP1 to SP3, holes injected from the anode electrode AE and electrons injected from the cathode electrode CE may be transported into the light emitting layer of the light emitting structure EMS to form excitons, and light may be generated when the excitons transit from an excited state to a ground state. A luminance of the light may be determined according to an amount of a current flowing through the light emitting layer. According to a configuration of the light emitting layer, a wavelength range of the generated light may be determined.

The encapsulation layer TFE is located on the cathode electrode CE. The encapsulation layer TFE may cover the light emitting element layer LDL and/or the pixel circuit layer PCL. The encapsulation layer TFE may prevent or substantially prevent oxygen, moisture, and/or the like from permeating to the light emitting element layer LDL. In some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material, such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB). However, the materials of the organic layer and the inorganic layer of the encapsulation layer TFE are not limited thereto.

The encapsulation layer TFE may further include a thin film including aluminum oxide (AlOx) to improve an encapsulation efficiency of the encapsulation layer TFE. The thin film including the aluminum oxide may be located on an upper surface of the encapsulation layer TFE facing the optical functional layer OFL, and/or a lower surface of the encapsulating layer TFE facing the light emitting element layer LDL.

The thin film including the aluminum oxide may be formed through an atomic layer deposition (ALD) method. However, the present disclosure is not limited thereto. The encapsulation layer TFE may further include a thin film including at least one of various suitable materials suitable for improving an encapsulation efficiency.

The optical functional layer OFL is located on the encapsulation layer TFE. The optical functional layer OFL may include a color filter layer CFL and a lens array LA.

The color filter layer CFL is located between the encapsulation layer TFE and the lens array LA. The color filter layer CFL may filter the light emitted from the light emitting structure EMS, and may selectively output light having a wavelength range or a color corresponding to each sub-pixel. The color filter layer CFL may include color filters CF respectively corresponding to the first to third sub-pixels SP1 to SP3, and each of the color filters CF may pass light having a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The lens array LA is located on the color filter layer CFL. The lens array LA may include lenses LS corresponding to the first to third sub-pixels SP1 to SP3, respectively. Each of the lenses LS may improve a light emission efficiency by outputting light emitted from the light emitting structure EMS to an intended path. The lens array LA may have a relatively high refractive index. For example, the lens array LA may have a refractive index higher than that of the overcoat layer OC. In some embodiments, the lenses LS may include an organic material. In some embodiments, the lenses LS may include an acrylic material. However, the material of the lenses LS is not limited thereto.

In some embodiments, compared to the opening OP of the pixel defining layer PDL, at least a portion of the color filters CF of the color filter layer CFL and at least a portion of the lenses LS of the lens array LA may be shifted in a direction parallel to or substantially parallel to the plane defined by the first and second directions DR1 and DR2. In more detail, in a central area of the display area DA, a center of the color filter and a center of the lens may be aligned with or overlap with a center of the corresponding opening OP of the pixel defining layer PDL in the third direction DR3. For example, in the central area of the display area DA, the opening OP of the pixel defining layer PDL may completely overlap with the corresponding color filter of the color filter layer CFL and the corresponding lens of the lens array LA. In an area in the display area DA adjacent to the non-display area NDA, the center of the color filter and the center of the lens may be shifted in a plane direction from the center of the corresponding opening OP of the pixel defining layer PDL in the third direction DR3. For example, in the area in the display area DA adjacent to the non-display area NDA, the opening OP of the pixel defining layer PDL may be partially overlap with the corresponding color filter of the color filter layer CFL and the corresponding lens of the lens array LA. Accordingly, at a center of the display area DA, the light emitted from the light emitting structure EMS may be efficiently output in a normal direction of a display surface. At an outskirt of the display area DA, the light emitted from the light emitting structure EMS may be efficiently output in a direction inclined by an angle (e.g., a predetermined angle) with respect to the normal direction of the display surface.

The overcoat layer OC may be located on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting the layers thereunder from a foreign substance, such as dust or moisture. For example, the overcoat layer OC may include at least one of an inorganic insulating layer or an organic insulating layer. For example, the overcoat layer OC may include an epoxy, but the present disclosure is not limited thereto. The overcoat layer OC may have a refractive index lower than that of the lens array LA.

The cover window CW may be located on the overcoat layer OC. The cover window CW may protect the layers thereunder. The cover window CW may have a refractive index higher than that of the overcoat layer OC. The cover window CW may include glass, but the present disclosure is not limited thereto. For example, the cover window CW may be an encapsulation glass to protect the components located thereunder. In other embodiments, the cover window CW may be omitted as needed or desired.

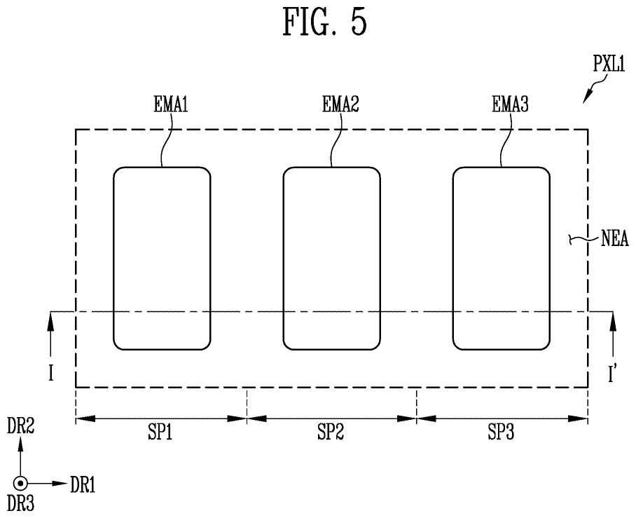

FIG. 5 is a plan view illustrating an embodiment of one of the pixels of FIG. 4. In FIG. 5, for convenience of illustration, the first pixel PXL1 of the first and second pixels PXL1 and PXL2 of FIG. 4 is schematically shown. The other remaining pixels PXL may be configured the same or substantially the same (or similarly) to that of the first pixel PXL1.

Referring to FIGS. 4 and 5, the first pixel PXL1 may include the first to third sub-pixels SP1 to SP3 arranged along the first direction DR1.

The first sub-pixel SP1 may include a first emission area EMA1, and a non-emission area NEA around the first emission area EMA1. The second sub-pixel SP2 may include a second emission area EMA2, and a non-emission area NEA around the second emission area EMA2. The third sub-pixel SP3 may include a third emission area EMA3, and a non-emission area NEA around the third emission area EMA3.

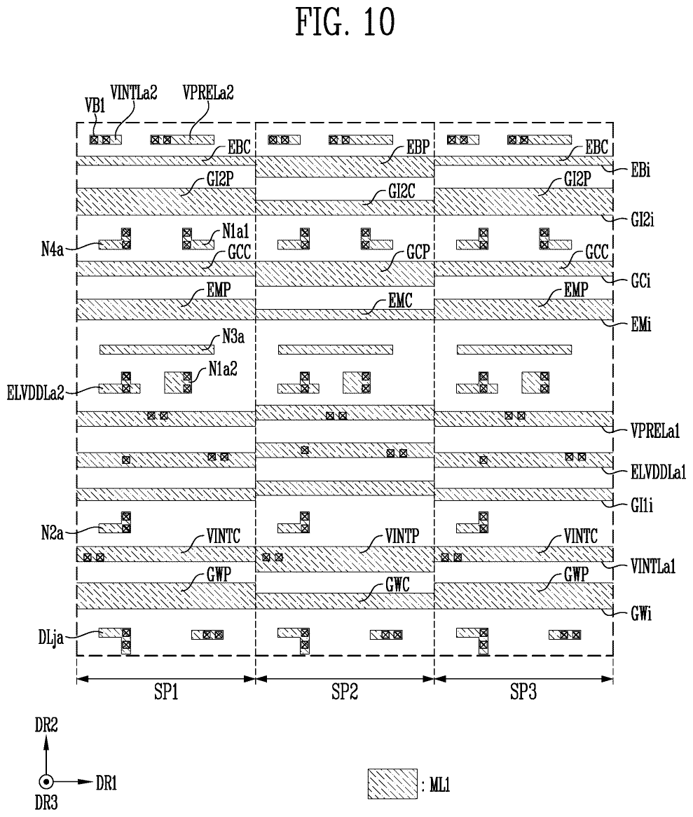

The first emission area EMA1 may be an area where light is emitted from a portion of the light emitting structure EMS (e.g., refer to FIG. 10) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3.

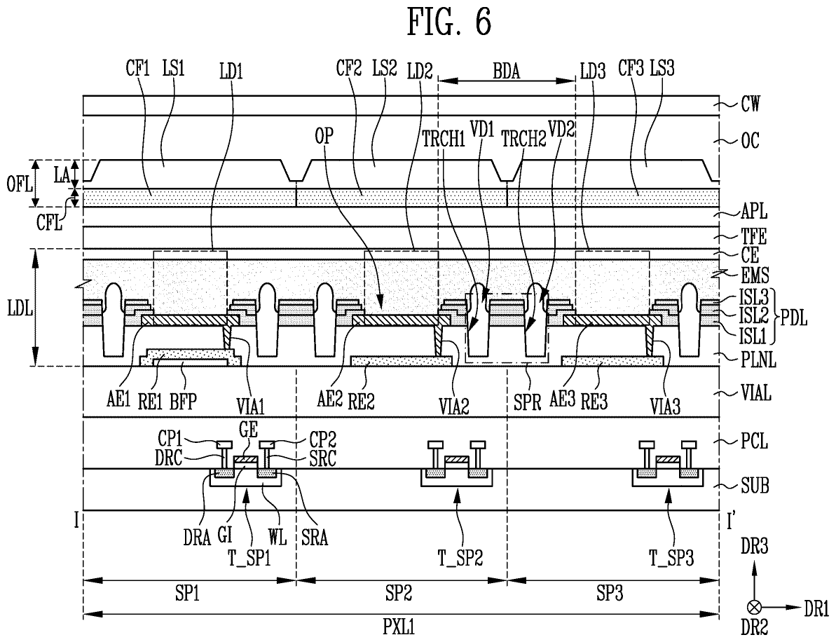

FIG. 6 is a cross-sectional view taken along the line I-I′ of FIG. 5 according to an embodiment.

Referring to FIG. 6, the substrate SUB, and the pixel circuit layer PCL located on the substrate SUB are shown.

The substrate SUB may include a silicon wafer substrate formed using a semiconductor process. For example, the substrate SUB may include silicon, germanium, and/or silicon-germanium.

The pixel circuit layer PCL is located on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (e.g., refer to FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for convenience of illustration, one of the transistors of each sub-pixel SP1, SP2, and SP3 is shown, and the other remaining circuit elements are not illustrated.

The transistor T_SP1 of the first sub-pixel SP1 may include a source area SRA, a drain area DRA, and a gate electrode GE.

The source area SRA and drain area DRA may be located in the substrate SUB. A well WL formed through an ion injection process may be located in the substrate SUB, and the source area SRA and the drain area DRA may be located to be spaced apart from each other in the well WL. An area between the source area SRA and the drain area DRA in the well WL may be defined as a channel area. The gate electrode GE may overlap with the channel area between the source area SRA and the drain area DRA, and may be located in the pixel circuit layer PCL. The gate electrode GE may be spaced apart from the well WL or the channel area by an insulating material, such as a gate insulating layer GI. The gate electrode GE may include a conductive material.

A plurality of layers included in the pixel circuit layer PCL may include insulating layers, and conductive patterns located between the insulating layers. The conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines from each other, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured the same or substantially the same as (or similarly to) that of the transistor T_SP1 of the first sub-pixel SP1.

As described above, the substrate SUB and the pixel circuit layer PCL may include the circuit elements of each of the first to third sub-pixels SP1 to SP3.

A via layer VIAL is located on the pixel circuit layer PCL. The via layer VIAL may cover the pixel circuit layer PCL, and may have an overall flat surface. The via layer VIAL may planarize steps on the pixel circuit layer PCL. The via layer VIAL may include at least one of silicon oxide (SiOx), silicon nitride (SiNx), or silicon carbon nitride (SiCN), but the present disclosure is not limited thereto.

The light emitting element layer LDL is located on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 are located in the first to third sub-pixels SP1 to SP3, respectively. Each of the first to third reflective electrodes RE1 to RE3 may contact a corresponding circuit element located in the pixel circuit layer PCL through a via passing through the via layer VIAL.

The first to third reflective electrodes RE1 to RE3 may function as a full mirror reflecting the light emitted from the light emitting structure EMS toward the display surface (e.g., toward the cover window CW). The first to third reflective electrodes RE1 to RE3 may include one or more metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or a suitable alloy of two or more selected from among them.

In some embodiments, a connection electrode may be located under each of the first to third reflective electrodes RE1 to RE3. The connection electrode may improve an electrical connection characteristic between a corresponding reflective electrode and a corresponding circuit element of the pixel circuit layer PCL. The connection electrode may have a multilayered structure. The multilayered structure may include titanium (Ti), titanium nitride (TiN), tantalum nitride (TaN), or the like, but the present disclosure is not limited thereto. In some embodiments, a corresponding reflective electrode may be located between multiple layers of the corresponding connection electrode.

A buffer pattern BFP may be located under at least one of the reflective electrodes RE1 to RE3. The buffer pattern BFP may include an inorganic material, such as silicon carbon nitride, but the present disclosure is not limited thereto. By disposing the buffer pattern BFP, a height in the third direction DR3 of a corresponding reflective electrode may be adjusted. For example, the buffer pattern BFP may be located between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. For example, each of the first to third reflective electrodes RE1 to RE3 and the cathode electrode CE may provide a resonance structure in a corresponding sub-pixel. The light emitted from the light emitting layer of the light emitting structure EMS may be amplified by reciprocating between a corresponding reflective electrode and the cathode electrode CE, and the amplified light may be output through the cathode electrode CE. As described above, a distance between each reflective electrode and the cathode electrode CE may be a resonance distance for the light emitted from the corresponding light emitting layer of the light emitting structure EMS.

The first sub-pixel SP1 may have a resonance distance shorter than that of the other sub-pixels by the buffer pattern BFP. The resonance distance adjusted as described above may allow light of a desired wavelength range (e.g., a specific or predetermined wavelength range, for example, such as a red color) to be effectively and efficiently amplified. Accordingly, the first sub-pixel SP1 may effectively and efficiently output light of a corresponding wavelength range.

In FIG. 6, the buffer pattern BFP is provided to the first sub-pixel SP1 and is not provided to the second and third sub-pixels SP2 and SP3, but the present disclosure is not limited thereto. The buffer pattern may also be provided in at least one of the second or third sub-pixels SP2 or SP3 to adjust the resonance distance of the at least one of the second or third sub-pixels SP2 or SP3. For example, the first to third sub-pixels SP1 to SP3 may correspond to red, green, and blue, respectively. In this case, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be located on the via layer VIAL and the first to third reflective electrodes RE1 to RE3, to planarize steps between the first to third reflective electrodes RE1 to RE3. The planarization layer PLNL may generally cover the first to third reflective electrodes RE1 to RE3 and the via layer VIAL, and may have a flat or substantially flat surface. In some embodiments, the planarization layer PLNL may be omitted as needed or desired.

On the planarization layer PLNL, first to third anode electrodes AE1 to AE3 respectively overlapping with the first to third reflective electrodes RE1 to RE3 are located. The first to third anode electrodes AE1 to AE3 may have shapes similar to those of the first to third emission areas EMA1 to EMA3 of FIG. 5 when viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

In some embodiments, the first to third anode electrodes AE1 to AE3 may include at least one of various suitable transparent conductive materials, such as indium tin oxide (ITO), indium zinc oxide (IZO), zinc oxide (ZnOₓ), indium gallium zinc oxide (IGZO), or indium tin zinc oxide (ITZO). However, the material of the first to third anode electrodes AE1 to AE3 is not limited thereto. For example, the first to third anode electrodes AE1 to AE3 may include titanium nitride.

The pixel defining layer PDL is located on portions of the first to third anode electrodes AE1 to AE3 and the planarization layer PLNL. The pixel defining layer PDL has the opening OP exposing a portion of each of the first to third anode electrodes AE1 to AE3. An area overlapping with the pixel defining layer PDL may be understood as a boundary area BDA between neighboring sub-pixels.

In some embodiments, the pixel defining layer PDL may include a plurality of inorganic insulating layers. Each of the plurality of inorganic insulating layers may include at least one of silicon oxide (SiOx) or silicon nitride (SiNx). For example, the pixel defining layer PDL may include a first inorganic insulating layer ISL1, a second inorganic insulating layer ISL2, and a third inorganic insulating layer ISL3 that are sequentially stacked. The first to third inorganic insulating layers ISL1 to ISL3 may include silicon nitride, silicon oxide, and silicon nitride, but the present disclosure is not limited thereto. The first to third inorganic insulating layers ISL1 to ISL3 may have a step-shaped cross-section in an area adjacent to the opening OP.

The pixel defining layer PDL may include a separator SPR in the boundary area BDA between neighboring sub-pixels. In other words, the separator SPR may be provided in each of the boundary areas between the sub-pixels SP of FIG. 3.

The separator SPR may cause a formation of a discontinuous portion in the light emitting structure EMS in the boundary area BDA. For example, the light emitting structure EMS may be disconnected or bent in the boundary area BDA due to the separator SPR. Therefore, the first to third emission areas EMA1 to EMA3 of FIG. 5 corresponding to the first to third sub-pixels SP1 to SP3 may be defined according to the separator SPR of the pixel defining layer PDL.

The separator SPR may be provided in or on the pixel defining layer PDL. The pixel defining layer PDL may include one or more trenches TRCH1 and TRCH2 as the separator SPR in the boundary area BDA. In some embodiments, as shown in FIG. 6, one or more trenches TRCH1 and TRCH2 may pass through the pixel defining layer PDL, and may partially pass through the planarization layer PLNL. In other embodiments, one or more trenches TRCH1 and TRCH2 may pass through the pixel defining layer PDL and the planarization layer PLNL, and may partially pass through the via layer VIAL. In other embodiments, one or more trenches TRCH1 and TRCH2 may at least partially pass through the planarization layer PLNL and/or the via layer VIAL, and a portion of the pixel defining layer PDL may be located in the one or more trenches TRCH1 and TRCH2.

In FIG. 6, two trenches TRCH1 and TRCH2 are illustrated in the boundary area BDA. However, the present disclosure is not limited thereto. For example, the pixel defining layer PDL may include one trench in the boundary area BDA. As another example, the pixel defining layer PDL may include three or more trenches in the boundary area BDA.

Due to the first and second trenches TRCH1 and TRCH2 in the boundary area BDA, discontinuous portions, such as a first void VD1 and a second void VD2, may be formed in the light emitting structure EMS. A portion of a plurality of layers stacked in the light emitting structure EMS may be disconnected or bent by the first and second voids VD1 and VD2. For example, at least one charge generation layer and at least one hole injection layer included in the light emitting structure EMS may be disconnected in the first and second voids VD1 and VD2. As described above, portions of the light emitting structure EMS included in the first to third sub-pixels SP1 to SP3 may be at least partially separated due to the first and second trenches TRCH1 and TRCH2.

According to shapes of the first and second trenches TRCH1 and TRCH2, the discontinuous portions formed in the light emitting structure EMS may be variously modified.

In some embodiments, the light emitting structure EMS may be formed through a process of vacuum deposition, inkjet printing, and the like. In this case, the same materials as that of the light emitting structure EMS may be located on bottom surfaces of the first and second trenches TRCH1 and TRCH2 adjacent to the via layer VIAL.

The pixel defining layer PDL may include an additional separator so that the light emitting structure EMS further includes a discontinuous portion adjacent to the boundary area BDA. In some embodiments, the third inorganic insulating layer ISL3 of an uppermost portion among the first to third inorganic insulating layers ISL1 to ISL3 of the pixel defining layer PDL may have a width wider than that of the second inorganic insulating layer ISL2 located directly thereunder. For example, the pixel defining layer PDL may have a “T” shape or an “I” shape of a cross-section in the boundary area BDA. According to a shape of the pixel defining layer PDL, a plurality of layers included in the light emitting structure EMS may be at least partially disconnected or bent in the boundary area BDA, or in an area adjacent to the boundary area BDA.

The light emitting structure EMS may be located on the anode electrodes AE1 to AE3 exposed by the opening OP of the pixel defining layer PDL. The light emitting structure EMS may fill the opening OP of the pixel defining layer PDL, and may be located entirely across the first to third sub-pixels SP1 to SP3. As described above, the light emitting structure EMS may be at least partially disconnected or bent in the boundary area BDA by the separator SPR. Accordingly, a current flowing out from each of the first to third sub-pixels SP1 to SP3 to a sub-pixel adjacent thereto through the layers included in the light emitting structure EMS may decrease when the display panel DP is operated. Therefore, first to third light emitting elements LD1 to LD3 may operate with a relatively higher reliability.

The cathode electrode CE may be located on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AE1, a portion of the light emitting structure EMS overlapping with the first anode electrode AE1, and a portion of the cathode electrode CE overlapping with the first anode electrode AE1 may configure the first light emitting element LD1. The second anode electrode AE2, a portion of the light emitting structure EMS overlapping with the second anode electrode AE2, and a portion of the cathode electrode CE overlapping with the second anode electrode AE2 may configure the second light emitting element LD2. The third anode electrode AE3, a portion of the light emitting structure EMS overlapping with the third anode electrode AE3, and a portion of the cathode electrode CE overlapping with the third anode electrode AE3 may configure the third light emitting element LD3.

The encapsulation layer TFE is located on the cathode electrode CE. The encapsulation layer TFE may prevent or substantially prevent oxygen, moisture, and/or the like from permeating to the light emitting element layer LDL.

The optical functional layer OFL is located on the encapsulation layer TFE. In some embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting the lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges from each other. For example, the first to third color filters CF1 to CF3 may pass light of red, green, and blue colors, respectively.

In some embodiments, the first to third color filters CF1 to CF3 may partially overlap with each other in the boundary area BDA. In other embodiments, the first to third color filters CF1 to CF3 may be spaced apart from each other, and a black matrix may be provided between the first to third color filters CF1 to CF3.

The lens array LA is located on the color filter layer CFL. The lens array LA may include first to third lenses LS1 to LS3 respectively corresponding to the first to third sub-pixels SP1 to SP3. Each of the first to third lenses LS1 to LS3 may improve a light output efficiency by outputting light emitted from the corresponding one of the first to third light emitting elements LD1 to LD3 to an intended path.

The overcoat layer OC may be located on the lens array LA. The overcoat layer OC may protect the lower layers thereof from a foreign substance, such as dust or moisture. The cover window CW may be located on the overcoat layer OC.

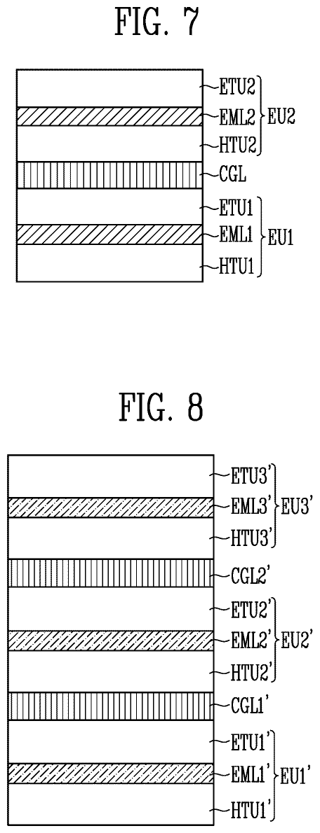

FIG. 7 is a cross-sectional view illustrating a portion of a light emitting structure included in one of the first to third light emitting elements of FIG. 6 according to an embodiment.

Referring to FIG. 7, the light emitting structure may have a tandem structure in which first and second light emitting units (e.g., first and second light emitting stacks) EU1 and EU2 are stacked on one another. The light emitting structure may be configured the same or substantially the same in each of the first to third light emitting elements LD1 to LD3 of FIG. 6.

Each of the first and second light emitting units EU1 and EU2 may include at least one light emitting layer that generates light according to an applied current. The first light emitting unit EU1 may include a first light emitting layer EML1, a first electron transport unit (e.g., a first electron transport layer or stack) ETU1, and a first hole transport unit (e.g., a first hole transport layer or stack) HTU1. The first light emitting layer EML1 may be located between the first electron transport unit ETU1 and the first hole transport unit HTU1. The second light emitting unit EU2 may include a second light emitting layer EML2, a second electron transport unit (e.g., a second electron transport layer or stack) ETU2, and a second hole transport unit (e.g., a second hole transport layer or stack) HTU2. The second light emitting layer EML2 may be located between the second electron transport unit ETU2 and the second hole transport unit HTU2.

Each of the first and second hole transport units HTU1 and HTU2 may include at least one of a hole injection layer or a hole transport layer, and may further include a hole buffer layer, an electron blocking layer, and/or the like, if necessary or desired. The first and second hole transport units HTU1 and HTU2 may have configurations that are the same or substantially the same as each other, or different from each other.

Each of the first and second electron transport units ETU1 and ETU2 may include at least one of an electron injection layer or an electron transport layer, and may further include an electron buffer layer, a hole blocking layer, and/or the like, if necessary or desired. The first and second electron transport units ETU1 and ETU2 may have configurations that are the same or substantially the same as each other, or different from each other.

A connection layer, which may be provided in a form of a charge generation layer CGL, may be located between the first light emitting unit EU1 and the second light emitting unit EU2, to connect the first light emitting unit EU1 and the second light emitting unit EU2 to each other. In some embodiments, the charge generation layer CGL may have a stack structure of a p dopant layer and an n dopant layer. For example, the p dopant layer may include a p-type dopant, such as HAT-CN, TCNQ, and/or NDP-9, and the n dopant layer may include an alkali metal, an alkaline earth metal, a lanthanide metal, or a suitable combination thereof. However, the present disclosure is not limited thereto.

In some embodiments, the first light emitting layer EML1 and the second light emitting layer EML2 may generate light of different colors from each other. Light emitted from each of the first light emitting layer EML1 and the second light emitting layer EML2 may be mixed together and viewed as white light. For example, the first light emitting layer EML1 may generate blue light, and the second light emitting layer EML2 may generate yellow light. In some embodiments, the second light emitting layer EML2 may include a structure in which a first sub light emitting layer to generate red light and a second sub light emitting layer to generate green light are stacked on one another. The red light and the green light may be mixed together, and thus, yellow light may be provided. In this case, an intermediate layer configured to perform a function of transporting holes and/or blocking the transport of electrons may be further located between the first and second sub light emitting layers.

In other embodiments, the first light emitting layer EML1 and the second light emitting layer EML2 may generate light of the same color as each other.

The light emitting structure may be formed through a suitable method of a vacuum deposition, an inkjet printing, and/or the like, but the present disclosure is not limited thereto.

FIG. 8 is a cross-sectional view illustrating a portion of the light emitting structure included in one of the first to third light emitting elements of FIG. 6 according to an embodiment.

Referring to FIG. 8, the light emitting structure may have a tandem structure in which first to third light emitting units (e.g., first to third light emitting stacks) EU1′ to EU3′ are stacked on one another. The light emitting structure may be configured the same or substantially the same in each of the first to third light emitting elements LD1 to LD3 of FIG. 6.

Each of the first to third light emitting units EU1′ to EU3′ may include a light emitting layer that generates light according to an applied current. The first light emitting unit EU1′ may include a first light emitting layer EML1′, a first electron transport unit (e.g., a first electron transport layer or stack) ETU1′, and a first hole transport unit (e.g., a first hole transport layer or stack) HTU1′. The first light emitting layer EML1′ may be located between the first electron transport unit ETU1′ and the first hole transport unit HTU1′. The second light emitting unit EU2′ may include a second light emitting layer EML2′, a second electron transport unit (e.g., a second electron transport layer or stack) ETU2′, and a second hole transport unit (e.g., a second hole transport layer or stack) HTU2′. The second light emitting layer EML2′ may be located between the second electron transport unit ETU2′ and the second hole transport unit HTU2′. The third light emitting unit EU3′ may include a third light emitting layer EML3′, a third electron transport unit (e.g., a third electron transport layer or stack) ETU3′, and a third hole transport unit (e.g., a third hole transport layer or stack) HTU3′. The third light emitting layer EML3′ may be located between the third electron transport unit ETU3′ and the third hole transport unit HTU3′.

Each of the first to third hole transport units HTU1′ to HTU3′ may include at least one of a hole injection layer or a hole transport layer, and may further include a hole buffer layer, an electron blocking layer, and/or the like, if necessary or desired.

The first to third hole transport units HTU1′ to HTU3′ may have configurations the same or substantially the same as each other, or different from each other.

Each of the first to third electron transport units ETU1′ to ETU3′ may include at least one of an electron injection layer or an electron transport layer, and may further include an electron buffer layer, a hole blocking layer, and/or the like, if necessary or desired. The first to third electron transport units ETU1′ to ETU3′ may have configurations the same or substantially the same as each other, or different from each other.

A first charge generation layer CGL1′ is located between the first light emitting unit EU1′ and the second light emitting unit EU2′. A second charge generation layer CGL2′ is located between the second light emitting unit EU2′ and the third light emitting unit EU3′.

In some embodiments, the first to third light emitting layers EML1′ to EML3′ may generate light of different colors from each other. Light emitted from each of the first to third light emitting layers EML1′ to EML3′ may be mixed together, and may be viewed as white light. For example, the first emitting layer EML1′ may generate light of a blue color, the second emitting layer EML2′ may generate light of a green color, and the third emitting layer EML3′ may generate light of a red color.

In other embodiments, two or more of the first to third light emitting layers EML1′ to EML3′ may generate light of the same color as each other.

Unlike that shown in FIGS. 7 and 8, the light emitting structure of FIG. 6 may include one light emitting unit (e.g., one light emitting layer or stack) in each of the first to third light emitting elements LD1 to LD3. In this case, the light emitting unit included in each of the first to third light emitting elements LD1 to LD3 may be configured to emit light of different colors from each other. For example, the light emitting unit of the first light emitting element LD1 may emit the light of the red color, the light emitting unit of the second light emitting element LD2′ may emit the light of the green light, and the light emitting unit of the third light emitting element LD3 may emit the light of the blue color. In this case, the light emitting units of the first to third sub-pixels SP1 to SP3 may be spaced apart (e.g., may be separated) from each other, and each of them may be located in a corresponding opening OP of the pixel defining layer PDL (e.g., refer to FIG. 6). In this case, at least a portion of the color filters CF1 to CF3 may be omitted as needed or desired.

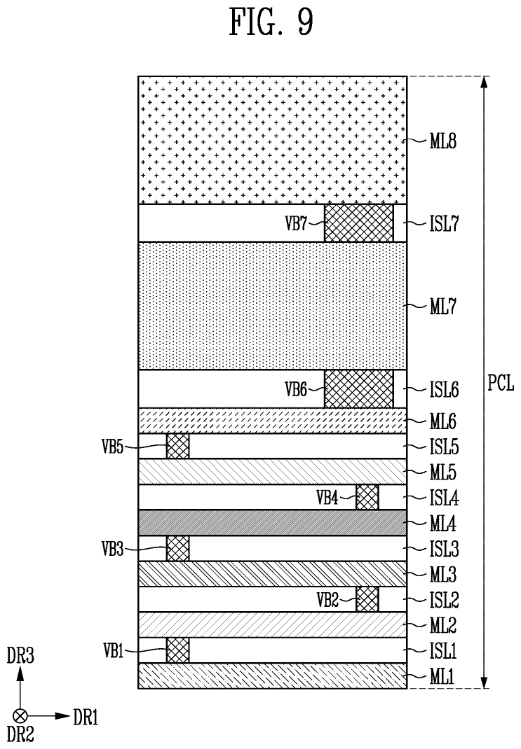

FIG. 9 is a drawing illustrating the pixel circuit layer of FIG. 6.

Referring to FIG. 9, the pixel circuit layer PCL may include first to eighth electrode layers ML1, ML2, ML3, ML4, ML5, ML6, ML7, and ML8, and first to seventh insulating layers ISL1, ISL2, ISL3, ISL4, ISL5, ISL6, and ISL7 interposed between the first to eighth electrode layers ML1 to ML8. Via electrodes VB1, VB2, VB3, VB4, VB5, VB6, and VB7 connecting corresponding upper and lower electrode layers to each other may be located in the first to seventh insulating layers ISL1 to ISL7, respectively.

The first to eighth electrode layers ML1 to ML8 and the via electrodes VB1 to VB7 may include a single layer of a conductor, or multiple layers of conductors. The conductor may include, for example, copper (Cu), aluminum (Al), tungsten (W), titanium (Ti), titanium nitride (TiN), tantalum nitride (TaN), or the like, but the present disclosure is not limited thereto, and other suitable conductors may be used.

Conductive patterns of the first electrode layer ML1 may be connected to a first electrode, a second electrode, and a gate electrode of transistors formed on the substrate SUB. For example, the first electrode or the second electrode of the transistor may correspond to the source area SRA or the drain area DRA of the transistor T_SP1, T_SP2, or T_SP3 (e.g., refer to FIG. 6). For example, the conductive patterns of the first electrode layer ML1 may include the first conductive pattern CP1, the second conductive pattern CP2, and the gate electrode GE, or a conductive pattern connected to the gate electrode GE, of the transistor T_SP1, T_SP2, or T_SP3. Between the first electrode layer ML1 and the substrate SUB, one or more electrode layers or via electrodes SRC and DRC may exist for connecting the first electrode layer ML1 and the substrate SUB to each other.

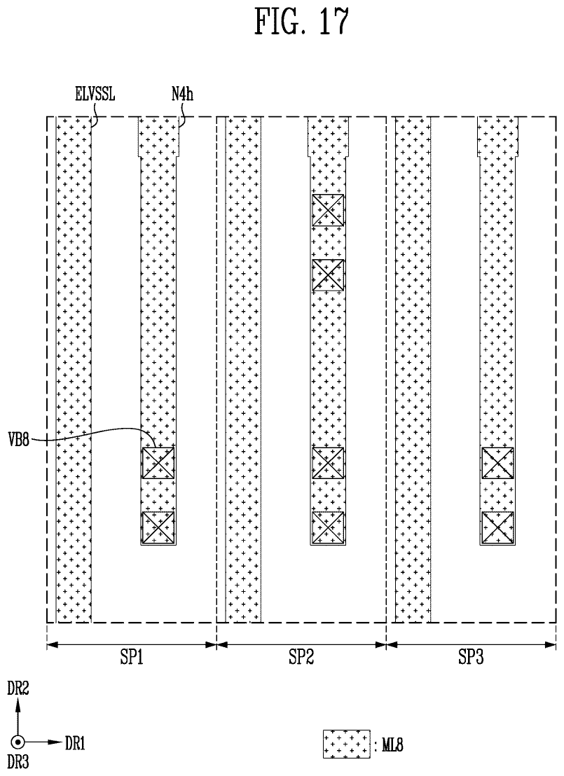

Conductive patterns of the eighth electrode layer ML8 may be connected to the reflective electrodes RE1, RE2, RE3, RE1′, RE2′, and RE3′, or other electrodes, through via electrodes VB8 located in the via layer VIAL (e.g., refer to FIGS. 6 and 17).

FIGS. 10 through 17 are drawings illustrating the electrode layers of FIG. 9.

Referring to FIG. 10, a layout of the first electrode layer ML1 for the first to third sub-pixels SP1, SP2, and SP3 is shown as a representative example.

The first electrode layer ML1 may include conductive patterns. The conductive patterns may include first conductive lines EBi, GI2i, GCi, EMi, VPRELa1, ELVDDLa1, GI1i, VINTLa1, and GWi extending in the first direction DR1 to be shared with the plurality of sub-pixels.

In this case, each of the conductive lines EBi, GI2i, GCi, EMi, VINTLa1, and GWi may repeatedly include a protrusion portion and a concave portion along the first direction DR1. In more detail, conductive lines most adjacent to each other in the second direction DR2 may include the protrusion portion and the concave portion that face each other. According to an embodiment, a separation distance in the second direction DR2 between the most adjacent conductive lines may be secured, thereby preventing or substantially preventing a short between the conductive lines.

For example, the most adjacent conductive lines may include the first gate line GWi and the first initialization line VINTLa1. In this case, the protrusion portion GWP of the first gate line GWi and the concave portion VINTC of the first initialization line VINTLa1 may face each other. The concave portion GWC of the first gate line GWi and the protrusion portion VINTP of the first initialization line VINTLa1 may face each other.

For example, the protrusion portion GWP of the first gate line GWi may be located on the first sub-pixel SP1 and the third sub-pixel SP3, and the concave portion GWC of the first gate line GWi may be located on the second sub-pixel SP2. The concave portion VINTC of the first initialization line VINTLa1 may be located on the first sub-pixel SP1 and the third sub-pixel SP3, and the protrusion portion VINTP of the first initialization line VINTLa1 may be located on the second sub-pixel SP2.

In an embodiment, a distance in the second direction DR2 between the protrusion portion GWP of the first gate line GWi and the concave portion VINTC of the first initialization line VINTLa1 may be equal to or substantially equal to a distance in the second direction DR2 between the concave portion GWC of the first gate line GWi and the protrusion portion VINTP of the first initialization line VINTLa1.

For example, the most adjacent conductive lines may include the second gate line GCi and the first emission control line EMi. In this case, the protrusion portion GCP of the second gate line GCi and the concave portion EMC of the first emission control line EMi may face each other. The concave portion GCC of the second gate line GCi and the protrusion portion EMP of the first emission control line EMi may face each other.

For example, the protrusion portion EMP of the first emission control line EMi may be located on the first sub-pixel SP1 and the third sub-pixel SP3, and the concave portion EMC of the first emission control line EMi may be located on the second sub-pixel SP2. The concave portion GCC of the second gate line GCi may be located on the first sub-pixel SP1 and the third sub-pixel SP3, and the protrusion portion GCP of the second gate line GCi may be located on the second sub-pixel SP2.

In an embodiment, a distance in the second direction DR2 between the protrusion portion GCP of the second gate line GCi and the concave portion EMC of the first emission control line EMi may be equal to or substantially equal to a distance in the second direction DR2 between the concave portion GCC of the second gate line GCi and the protrusion portion EMP of the first emission control line EMi.

For example, the most adjacent conductive lines may include the fourth gate line GI2i and the second emission control line EBi. In this case, the protrusion portion GI2P of the fourth gate line GI2i and the concave portion EBC of the second emission control line EBi may face each other. The concave portion GI2C of the fourth gate line GI2i and the protrusion portion EBP of the second emission control line EBi may face each other.

For example, the protrusion portion GI2P of the fourth gate line GI2i may be located on the first sub-pixel SP1 and the third sub-pixel SP3, and the concave portion GI2C of the fourth gate line GI2i may be located on the second sub-pixel SP2. The concave portion EBC of the second emission control line EBi may be located on the first sub-pixel SP1 and the third sub-pixel SP3, and the protrusion portion EBP of the second emission control line EBi may be located on the second sub-pixel SP2.

In an embodiment, a distance in the second direction DR2 between the protrusion portion GI2P of the fourth gate line GI2i and the concave portion EBC of the second emission control line EBi may be equal to or substantially equal to a distance in the second direction DR2 between the concave portion GI2C of the fourth gate line GI2i and the protrusion portion EBP of the second emission control line EBi.

The second initialization line VPRELa1, the first power line ELVDDLa1, and the third gate line GI1i may extend in a zigzag form along the first direction DR1. For example, coordinates in the second direction DR2 of the second initialization line VPRELa1, the first power line ELVDDLa1, and the third gate line GI1i may vary in a sub-pixel unit. According to an embodiment, a short of three or more adjacent conductive lines may be effectively prevented.

In addition, the first electrode layer ML1 may include a plurality of conductive patterns. A shape and a position of the conductive patterns of the first electrode layer ML1 may be commonly applied to the sub-pixels SP1, SP2, and SP3. In other words, the above description is based on the first sub-pixel SP1.

Conductive pattern VINTLa2 may be connected to a first initialization line VINTLb of the second electrode layer ML2 through the via electrode VB1 (e.g., refer to FIG. 15). A conductive pattern N4a may be connected to a conductive pattern N4b of the second electrode layer ML2 through the via electrode VB1. Conductive patterns N4a and N4b may correspond to the fourth node N4 of the sub-pixel circuit SPC of FIG. 2. For example, the first electrode of the fifth transistor T5 may be connected to the conductive pattern N4a, the second electrode may be connected to the conductive pattern VINTLa2, and the gate electrode may be connected to the second emission control line EBi.

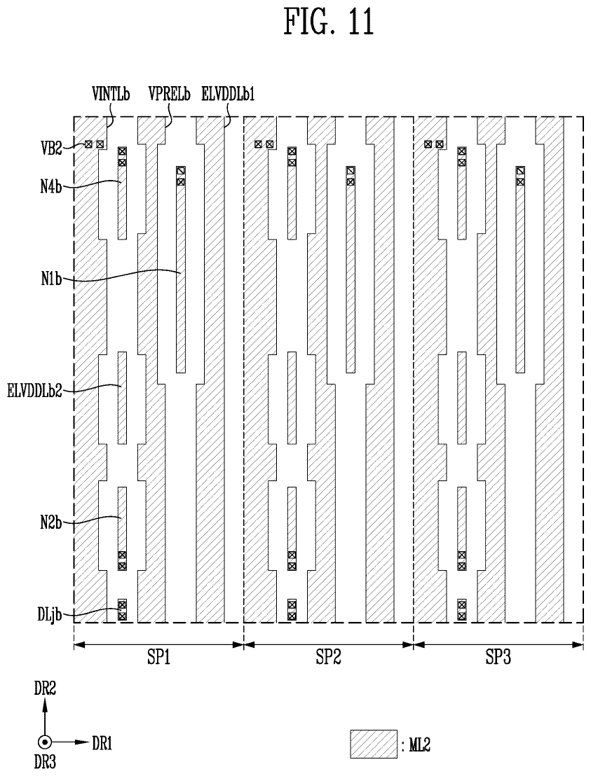

A conductive pattern VPRELa2 may be connected to a second initialization line VPRELb of the second electrode layer ML2 through the via electrode VB1 (e.g., refer to FIG. 11). A conductive pattern N1a1 and a conductive pattern N1a2 may be connected to a conductive pattern N1b of the second electrode layer ML2 through the via electrode VB1. The conductive patterns N1a1, N1a2, and N1b may correspond to the first node N1 of the sub-pixel circuit SPC of FIG. 2. For example, the first electrode of the seventh transistor T5 may be connected to the conductive pattern VPRELa2, the second electrode may be connected to the conductive pattern N1a1, and the gate electrode may be connected to the fourth gate line GI2i.

A conductive pattern N3a may correspond to the third node N3 of the sub-pixel circuit SPC of FIG. 2. For example, the first electrode of the third transistor T3 may be connected to the conductive pattern N1a1, the second electrode may be connected to the conductive pattern N3a, and the gate electrode may be connected to the second gate line GCi. The first electrode of the fourth transistor T4 may be connected to the conductive pattern N3a, the second electrode may be connected to the conductive pattern N4a, and the gate line may be connected to the first emission control line EMi.

A conductive pattern ELVDDLa2 and the first power line ELVDDLa1 may be connected to a conductive pattern ELVDDLb2 of the second electrode layer ML2 through the via electrode VB1. For example, the first electrode of the first transistor T1 may be connected to the conductive pattern ELVDDLa2, the second electrode may be connected to the conductive pattern N3a, and the gate electrode may be connected to the conductive pattern N1a2.

A conductive pattern N2a may be connected to a conductive pattern N2b of the second electrode layer ML2 through the via electrode VB1 (e.g., refer to FIG. 11). The conductive patterns N2a and N2b may correspond to the second node N2 of the sub-pixel circuit SPC of FIG. 2. For example, the first electrode of the sixth transistor T6 may be connected to the second initialization line VPRELa1, the second electrode may be connected to the conductive pattern N2a, and the gate electrode may be connected to the third gate line GI1i.

A conductive pattern DLja may be connected to a conductive pattern DLjb of the second electrode layer ML2 through the via electrode VB1 (e.g., refer to FIG. 11). The conductive patterns DLja and DLjb may correspond to the data line DLj. For example, the first electrode of the second transistor T2 may be connected to the conductive pattern DLja, the second electrode may be connected to the conductive pattern N2a, and the gate electrode may be connected to the first gate line GWi.

Referring to FIG. 11, a layout of the second electrode layer ML2 for the first to third sub-pixels SP1, SP2, and SP3 is shown as a representative example.

The second electrode layer ML2 may include conductive patterns. The conductive patterns may include island patterns N4b, N1b, ELVDDLb2, N2b, and DLjb extending in the second direction DR2, and second conductive lines VINTLb, VPRELb, and ELVDDLb1 extending in the second direction DR2. The second conductive lines VINTLb, VPRELb, and ELVDDLb1 may be dedicated lines for each of the sub-pixels.

Each of the second conductive lines VINTLb, VPRELb, and ELVDDLb1 may include a concave portion corresponding to an adjacent island pattern. For example, between the concave portions of the first initialization line VINTLb and the concave portions of the second initialization line VPRELb, the island patterns N2b, N4b, and ELVDDLb2 corresponding to the second node N2, the fourth node N4, and the first power line ELVDDL may be located. Between the concave portions of the second initialization line VPRELb and the concave portions of the first power line ELVDDLb1, the island pattern N1b corresponding to the first node N1 may be located.

In FIG. 11, with respect to the island pattern DLjb corresponding to the data line DLj, the first initialization line VINTLb and the second initialization line VPRELb may not include concave portions. However, in another embodiment, the first initialization line VINTLb and the second initialization line VPRELb may be configured so that the island pattern DLjb is located between a concave portion of the first initialization line VINTLb and a concave portion of the second initialization line VPRELb.

According to an embodiment, a short between adjacent conductive patterns may be effectively prevented.

Some conductive patterns of the second electrode layer ML2 may be connected to conductive patterns of the third electrode layer ML3 through the via electrodes VB2.

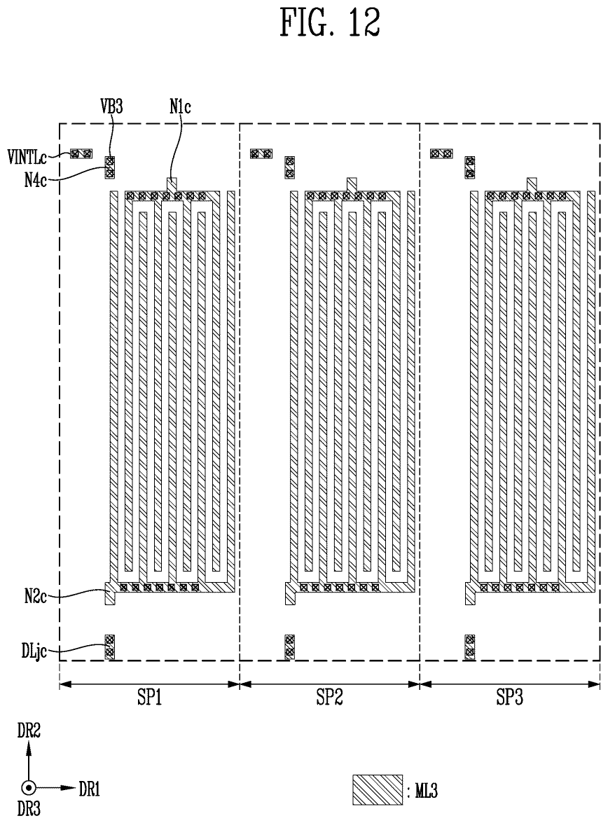

Referring to FIG. 12, a layout of the third electrode layer ML3 for the first to third sub-pixels SP1, SP2, and SP3 is shown as a representative example.

The third electrode layer ML3 may include a conductive pattern VINTLc corresponding to the first initialization line VINTL, a conductive pattern N4c corresponding to the fourth node N4, a conductive pattern N1c corresponding to the first node N1, a conductive pattern N2c corresponding to the second node N2, and a conductive pattern DLjc corresponding to the data line DLj.

In more detail, the conductive pattern N1c and the conductive pattern N2c may have a comb shape crossing (or interlocking with) each other, and may configure a portion of the capacitor C1 of the sub-pixel circuit SPC of FIG. 2.

Some conductive patterns of the third electrode layer ML3 may be connected to conductive patterns of the fourth electrode layer ML4 through the via electrodes VB3.

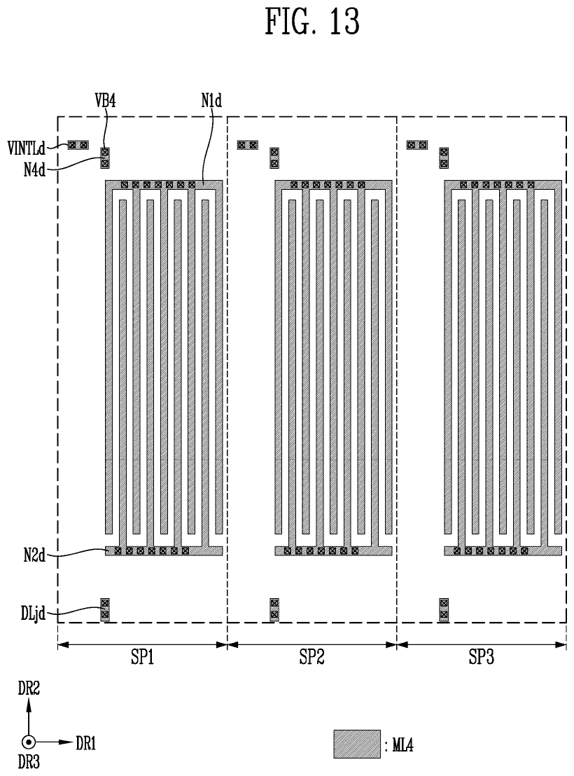

Referring to FIG. 13, a layout of the fourth electrode layer ML4 for the first to third sub-pixels SP1, SP2, and SP3 is shown as a representative example.

The fourth electrode layer ML4 may include a conductive pattern VINTLd corresponding to the first initialization line VINTL, a conductive pattern N4d corresponding to the fourth node N4, a conductive pattern N1d corresponding to the first node N1, a conductive pattern N2d corresponding to the second node N2, and a conductive pattern DLjd corresponding to the data line DLj.

In more detail, the conductive pattern N1d and the conductive pattern N2d may have a comb shape crossing (or interlocking with) each other, and may configure a portion of the capacitor C1 of the sub-pixel circuit SPC of FIG. 2.

Some conductive patterns of the fourth electrode layer ML4 may be connected to conductive patterns of the fifth electrode layer ML5 through the via electrodes VB4.

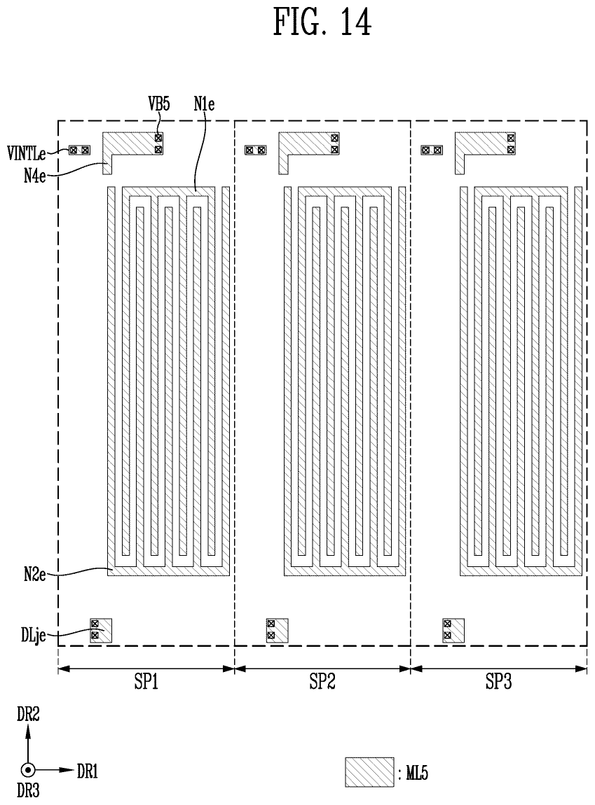

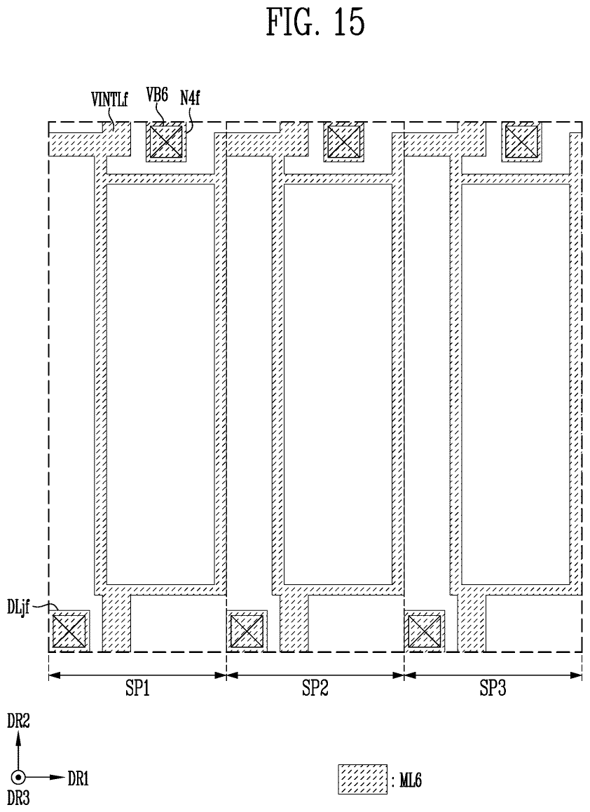

Referring to FIG. 14, a layout of the fifth electrode layer ML5 for the first to third sub-pixels SP1, SP2, and SP3 is shown as a representative example.

The fifth electrode layer ML5 may include a conductive pattern VINTLe corresponding to the first initialization line VINTL, a conductive pattern N4e corresponding to the fourth node N4, a conductive pattern N1e corresponding to the first node N1, a conductive pattern N2e corresponding to the second node N2, and a conductive pattern DLje corresponding to the data line DLj.

In more detail, the conductive pattern N1e and the conductive pattern N2e may have a comb shape crossing (or interlocking with) each other, and may configure a portion of the capacitor C1 of the sub-pixel circuit SPC of FIG. 2.

Some conductive patterns of the fifth electrode layer ML5 may be connected to conductive patterns of the sixth electrode layer ML6 through the via electrodes VB5.

Referring to FIG. 15, a layout of the sixth electrode layer ML6 for the first to third sub-pixels SP1, SP2, and SP3 is shown as a representative example.

The sixth electrode layer ML6 may include a conductive pattern VINTLf corresponding to the first initialization line VINTL, a conductive pattern N4f corresponding to the fourth node N4, and a conductive pattern DLjf corresponding to the data line DLj.

In this case, the conductive pattern VINTLf may be integrally configured with respect to the plurality of sub-pixels SP1, SP2, and SP3. In another embodiment, the conductive pattern VINTLf may be individually (e.g., separately) configured with respect to the plurality of sub-pixels SP1, SP2, and SP3.

Some conductive patterns of the sixth electrode layer ML6 may be connected to conductive patterns of the seventh electrode layer ML7 through the via electrodes VB6.

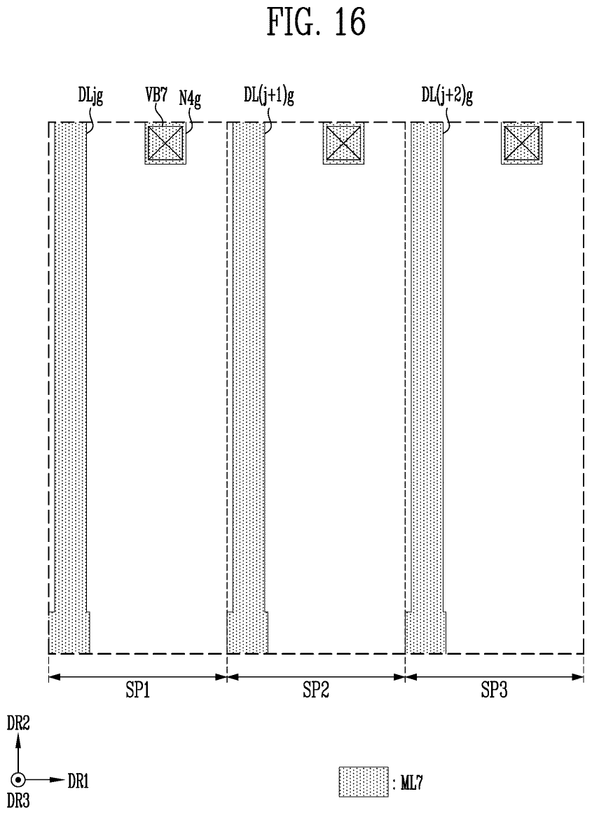

Referring to FIG. 16, a layout of the seventh electrode layer ML7 for the first to third sub-pixels SP1, SP2, and SP3 is shown as a representative example.

The seventh electrode layer ML7 may include a conductive pattern N4g corresponding to the fourth node N4, and a conductive pattern DLjg corresponding to the data line DLj. The second sub-pixel SP2 may include a conductive pattern DL(j+1)g corresponding to a (j+1)-th data line. In addition, the third sub-pixel SP3 may include a conductive pattern DL(j+2)g corresponding to a (j+2)-th data line.

Some conductive patterns of the seventh electrode layer ML7 may be connected to conductive patterns of the eighth electrode layer ML8 through the via electrodes VB7.

Referring to FIG. 17, a layout of the eighth electrode layer ML8 for the first to third sub-pixels SP1, SP2, and SP3 is shown as a representative example.

The eighth electrode layer ML8 may include a conductive pattern N4h corresponding to the fourth node N4 and the second power line ELVSSL. The conductive pattern N4h may be connected to a corresponding reflective electrode RE1, RE2, RE3, RE1′, RE2′, or RE3′ through the via electrode VB8 (e.g., refer to FIG. 6). In some embodiments, the second power line ELVSSL may be connected to the reflective electrode through the via electrode VB8, and the connected reflective electrode may be connected to the cathode electrode CE again.

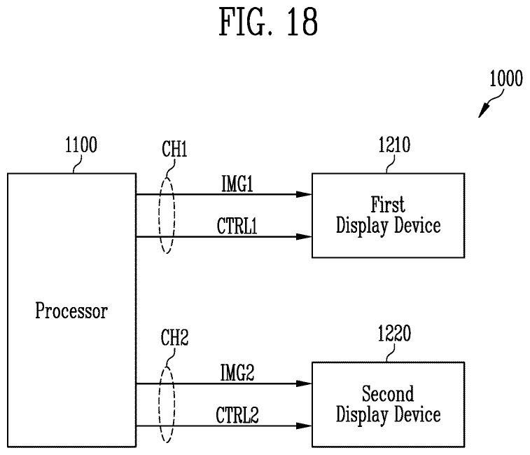

FIG. 18 is a block diagram illustrating a display system according to an embodiment.

Referring to FIG. 18, the display system 1000 may include a processor 1100 and one or more display devices 1210 and 1220.

The processor 1100 may perform various suitable tasks and calculations. In some embodiments, the processor 1100 may include an application processor, a graphic processor, a microprocessor, a central processing unit (CPU), and/or the like. The processor 1100 may be connected to the other components of the display system 1000 through a bus system, and may control the other components.

In FIG. 18, the display system 1000 includes first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured the same or substantially the same as (or similarly to) the display device 100 described above with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured the same or substantially the same as (or similarly to) the display device 100 described above with reference to FIG. 1. In this case, the second image data IMG2 and the second control signal CTRL2 may be provided as the input image data IMG and the control signal CTRL of FIG. 1, respectively.

The display system 1000 may include a computing system for providing an image display function, such as a portable computer, a mobile phone, a smart phone, a tablet personal computer (PC), a smart watch, a watch phone, a portable multimedia player (PMP), a navigation device, and/or an ultra mobile personal computer (UMPC). In addition, the display system 1000 may include at least one of a head mounted display (HMD) device, a virtual reality (VR) device, a mixed reality (MR) device, or an augmented reality (AR) device.

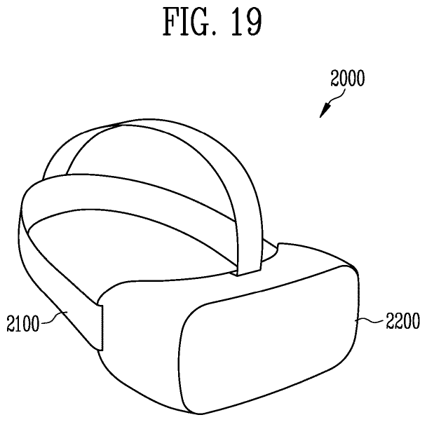

FIG. 19 is a perspective view illustrating an application example of the display system of FIG. 18.

Referring to FIG. 19, the display system 1000 of FIG. 18 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may surround a side portion of the user's head, and the vertical band may surround an upper portion of the user's head. However, the present disclosure is not limited thereto. For example, the head mount band 2100 may be implemented in a glasses frame form, a helmet form, or the like.

The display device receiving case 2200 may receive the first and second display devices 1210 and 1220 of FIG. 18. The display device receiving case 2200 may further receive the processor 1100 of FIG. 18.

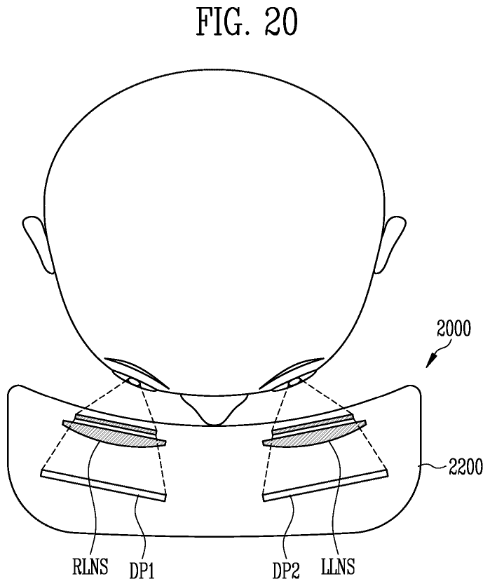

FIG. 20 is a diagram illustrating the head mounted display device of FIG. 19 worn by a user.

Referring to FIG. 20, in a head mounted display device 2000, a first display panel DP1 of the first display device 1210 and a second display panel DP2 of the second display device 1220 are located. The head mounted display device 2000 may further include one or more lenses LLNS and RLNS.

Within the display device receiving case 2200, the right eye lens RLNS may be located between the first display panel DP1 and a user's right eye. Within the display device receiving case 2200, the left eye lens LLNS may be located between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In some embodiments, each of the right eye lens RLNS and the left eye lens LLNS may include an optical lens having a pancake-shaped cross-section. In some embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas to be viewed by the user.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate having transistors of sub-pixels thereon; and
a first electrode layer on the substrate, and comprising first conductive patterns connected to a first electrode, a second electrode, and a gate electrode of the transistors,
wherein the first conductive patterns comprise first conductive lines extending in a first direction to be shared with a plurality of the sub-pixels,
wherein each of the first conductive lines repeatedly comprises a protrusion portion and a concave portion along the first direction, and
wherein the protrusion portion and the concave portion of one first conductive line face the concave portion and the protrusion portion, respectively, of another first conductive line adjacent to the one first conductive line in a second direction crossing the first direction from among the first conductive lines.

2. The display device according to claim 1, wherein each of the sub-pixels comprises:
a first transistor comprising a gate electrode connected to a first node, a first electrode connected to a first power line, and a second electrode connected to a third node;
a second transistor comprising a gate electrode connected to a first gate line, a first electrode connected to a data line, and a second electrode connected to a second node;
a third transistor comprising a gate electrode connected to a second gate line, a first electrode connected to the first node, and a second electrode connected to the third node;
a fourth transistor comprising a gate electrode connected to a first emission control line, a first electrode connected to the third node, and a second electrode connected to a fourth node;
a fifth transistor comprising a gate electrode connected to a second emission control line, a first electrode connected to the fourth node, and a second electrode connected to a first initialization line;
a sixth transistor comprising a gate electrode connected to a third gate line, a first electrode connected to a second initialization line, and a second electrode connected to the second node; and
a seventh transistor comprising a gate electrode connected to a fourth gate line, a first electrode connected to the second initialization line, and a second electrode connected to the first node.

3. The display device according to claim 2, wherein the one first conductive line and the other first conductive line comprise the first gate line and the first initialization line that are adjacent to each other in the second direction,
wherein the protrusion portion of the first gate line and the concave portion of the first initialization line face each other, and
wherein the concave portion of the first gate line and the protrusion portion of the first initialization line face each other.

4. The display device according to claim 3, wherein a distance in the second direction between the protrusion portion of the first gate line and the concave portion of the first initialization line is equal to a distance in the second direction between the concave portion of the first gate line and the protrusion portion of the first initialization line.

5. The display device according to claim 3, wherein the protrusion portion of the first gate line is located on a first sub-pixel and a third sub-pixel from among the sub-pixels,
wherein the concave portion of the first gate line is located on a second sub-pixel between the first sub-pixel and the third sub-pixel from among the sub-pixels,
wherein the concave portion of the first initialization line is located on the first sub-pixel and the third sub-pixel, and
wherein the protrusion portion of the first initialization line is located on the second sub-pixel.

6. The display device according to claim 2, wherein the one first conductive line and the other first conductive line comprise the second gate line and the first emission control line that are adjacent to each other in the second direction,
wherein the protrusion portion of the second gate line and the concave portion of the first emission control line face each other, and
wherein the concave portion of the second gate line and the protrusion portion of the first emission control line face each other.

7. The display device according to claim 6, wherein a distance in the second direction between the protrusion portion of the second gate line and the concave portion of the first emission control line is equal to a distance in the second direction between the concave portion of the second gate line and the protrusion portion of the first emission control line.

8. The display device according to claim 6, wherein the protrusion portion of the first emission control line is located on a first sub-pixel and a third sub-pixel from among the sub-pixels,
wherein the concave portion of the first emission control line is located on a second sub-pixel between the first sub-pixel and the third sub-pixel from among the sub-pixels,
wherein the concave portion of the second gate line is located on the first sub-pixel and the third sub-pixel, and
wherein the protrusion portion of the second gate line is located on the second sub-pixel.

9. The display device according to claim 2, wherein the one first conductive line and the other first conductive line comprise the fourth gate line and the second emission control line that are adjacent to each other in the second direction,
wherein the protrusion portion of the fourth gate line and the concave portion of the second emission control line face each other, and
wherein the concave portion of the fourth gate line and the protrusion portion of the second emission control line face each other.

10. The display device according to claim 9, wherein a distance in the second direction between the protrusion portion of the fourth gate line and the concave portion of the second emission control line is equal to a distance in the second direction between the concave portion of the fourth gate line and the protrusion portion of the second emission control line.

11. The display device according to claim 9, wherein the protrusion portion of the fourth gate line is located on a first sub-pixel and a third sub-pixel from among the sub-pixels,
wherein the concave portion of the fourth gate line is located on a second sub-pixel between the first sub-pixel and the third sub-pixel from among the sub-pixels,
wherein the concave portion of the second emission control line is located on the first sub-pixel and the third sub-pixel, and
wherein the protrusion portion of the second emission control line is located on the second sub-pixel.

12. The display device according to claim 2, wherein each of the second initialization line, the first power line, and the third gate line extends in a zigzag form along the first direction.

13. The display device according to claim 12, wherein coordinates in the second direction of the second initialization line, the first power line, and the third gate line vary in a unit of a sub-pixel.

14. The display device according to claim 2, further comprising a second electrode layer on the first electrode layer, and comprising second conductive patterns connected to the first conductive patterns,
wherein the second conductive patterns comprise island patterns and second conductive lines extending in the second direction, and
wherein each of the second conductive lines comprises a concave portion corresponding to an adjacent island pattern from among the island patterns.

15. The display device according to claim 14, wherein the second conductive lines comprise dedicated lines of respective sub-pixels from among the sub-pixels.

16. The display device according to claim 14, wherein the second conductive lines comprise the first initialization line, the second initialization line, and the first power line.

17. The display device according to claim 16, wherein the island patterns comprise the first node, the second node, the fourth node, the data line, and the first power line.

18. The display device according to claim 17 wherein island patterns corresponding to the second node, the fourth node, and the first power line from among the island patterns are located between concave portions of the first initialization line and concave portions of the second initialization line, and
wherein an island pattern corresponding to the first node from among the island patterns is located between a concave portion of the second initialization line and a concave portion of the first power line.

19. The display device according to claim 2, wherein each of the sub-pixels further comprises:
a capacitor between the first node and the second node; and
a light emitting element comprising an anode electrode connected to the fourth node, and a cathode electrode connected to a second power line.

20. An electronic device comprising:
a processor configured to provide image data; and
a display device configured to display an image based on the image data, the display device comprising:
a substrate having transistors of sub-pixels thereon; and
a first electrode layer on the substrate, and comprising first conductive patterns connected to a first electrode, a second electrode, and a gate electrode of the transistors,
wherein the first conductive patterns comprise first conductive lines extending in a first direction to be shared with a plurality of the sub-pixels,
wherein each of the first conductive lines repeatedly comprises a protrusion portion and a concave portion along the first direction, and
wherein the first conductive lines adjacent to each other in a second direction crossing the first direction from among the first conductive lines comprise the protrusion portion and the concave portion that face each other.
